(19) United States
(12) Patent Application Publication
(10) Pub. No.: US 2024/0315085 A1
(43) Pub. Date: Sep. 19, 2024

(54) MOTHER SUBSTRATE FOR DISPLAY DEVICE, DISPLAY DEVICE AND MANUFACTURING METHOD OF DISPLAY DEVICE

(71) Applicant: Japan Display Inc., Tokyo (JP)

(72) Inventors: Kazumi IIZAWA, Tokyo (JP); Ryota TAKASAKI, Tokyo (JP); Sho YANAGISAWA, Tokyo (JP)

(73) Assignee: Japan Display Inc., Tokyo (JP)

(21) Appl. No.: 18/582,879

(22) Filed: Feb. 21, 2024

(30) Foreign Application Priority Data
Mar. 17, 2023 (JP) 2023-043081

(51) Int. Cl. H10K 59/122; H10K 59/12; H10K 59/131

(52) U.S. Cl. CPC H10K 59/122; H10K 59/1201; H10K 59/131

(57) ABSTRACT

According to one embodiment, a mother substrate includes a substrate including a linear first side, a plurality of panel portions, a margin portion provided on an external side relative to the panel portions, and a first partition including a first lower portion provided in the margin portion, and a first upper portion provided on the first lower portion and protruding from a side surface of the first lower portion. The first partition has a shape which is not orthogonal to an extension direction of the first side.

### CROSS-REFERENCE TO RELATED APPLICATION

This application is based upon and claims the benefit of priority from Japanese Patent Application No. 2023-043081, filed Mar. 17, 2023, the entire contents of which are incorporated herein by reference.

### FIELD

Embodiments described herein relate generally to a mother substrate for a display device, a display device and a manufacturing method of a display device.

### BACKGROUND

Recently, display devices to which an organic light emitting diode (OLED) is applied as a display element have been put into practical use. This display element comprises a pixel circuit including a thin-film transistor, a lower electrode connected to the pixel circuit, an organic layer which covers the lower electrode, and an upper electrode which covers the organic layer. The organic layer includes functional layers such as a hole transport layer and an electron transport layer in addition to a light emitting layer.

In the process of manufacturing such a display element, a technique which prevents the reduction in reliability has been required.

### BRIEF DESCRIPTION OF THE DRAWINGS

FIG. 1 is a diagram showing a configuration example of a display device DSP.

FIG. 2 is a diagram showing an example of the layout of subpixels SP1, SP2 and SP3.

FIG. 3 is a schematic cross-sectional view of the display device DSP along the A-B line of FIG. 2.

FIG. 4 is a plan view showing an example of a mother substrate 100.

FIG. 5 is a cross-sectional view of the mother substrate 100 along the C-D line of FIG. 4.

FIG. 6 is a diagram for explaining the manufacturing method of the display device DSP.

FIG. 7 is a diagram for explaining the manufacturing method of the display device DSP.

FIG. 8 is a diagram for explaining the manufacturing method of the display device DSP.

FIG. 9 is a diagram for explaining application direction DX of a resist R1.

FIG. 10 is a diagram for explaining application direction DY of the resist R1.

FIG. 11 is a diagram for explaining the manufacturing method of the display device DSP.

FIG. 12 is a diagram for explaining the manufacturing method of the display device DSP.

FIG. 13 is a diagram for explaining the manufacturing method of the display device DSP.

FIG. 14 is a diagram for explaining the manufacturing method of the display device DSP.

FIG. 15 is a diagram for explaining the manufacturing method of the display device DSP.

FIG. 16 is a diagram for explaining the manufacturing method of the display device DSP.

FIG. 17 is a diagram for explaining the manufacturing method of the display device DSP.

FIG. 18 is a diagram showing another configuration example of a partition 7.

FIG. 19 is a diagram showing another configuration example of the partition 7.

FIG. 20 is a diagram showing another configuration example of the partition 7.

FIG. 21 is a cross-sectional view for explaining a comparative example which does not comprise the partition 7.

FIG. 22 is a cross-sectional view for explaining the embodiment which comprises the partition 7.

FIG. 23 is a diagram showing another configuration example of the partition 7.

FIG. 24 is a diagram showing another configuration example of the partition 7.

FIG. 25 is a diagram showing another configuration example of the partition 7.

FIG. 26 is a diagram showing another configuration example of the partition 7.

FIG. 27 is a diagram showing another configuration example of the partition 7.

FIG. 28 is a diagram showing another configuration example of the partition 7.

FIG. 29 is a diagram showing another configuration example of the partition 7.

FIG. 30 is a diagram showing another configuration example of the partition 7.

### DETAILED DESCRIPTION

Embodiments described herein aim to provide a mother substrate for a display device, a display device and a manufacturing method of a display device such that the reduction in reliability can be prevented.

In general, according to one embodiment, a mother substrate for a display device comprises a substrate comprising a linear first side, a plurality of panel portions, a margin portion provided on an external side relative to the panel portions, and a first partition comprising a first lower portion provided in the margin portion, and a first upper portion provided on the first lower portion and protruding from a side surface of the first lower portion. The first partition has a shape which is not orthogonal to an extension direction of the first side.

According to another embodiment, a display device comprises a display area which displays an image, a surrounding area provided on an external side relative to the display area, a plurality of terminals arranged in a single direction in the surrounding area, and a first partition comprising a first lower portion provided in the surrounding area, and a first upper portion provided on the first lower portion and protruding from a side surface of the first lower portion. The first partition has a shape which is not orthogonal to at least one of an arrangement direction of the terminals and a perpendicular direction orthogonal to the arrangement direction.

According to yet another embodiment, a manufacturing method of a display device comprises forming a lower electrode in a display area which displays an image, forming an inorganic insulating layer over the display area and a surrounding area provided on an external side relative to the display area, forming, in the surrounding area, a first partition comprising a first lower portion located on the inorganic insulating layer, and a first upper portion located on the first lower portion and protruding from a side surface of the first lower portion, and applying a resist. The first partition has a shape which is not orthogonal to an application direction of the resist.

The embodiments can provide a mother substrate for a display device, a display device and a manufacturing method of a display device such that the reduction in reliability can be prevented.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction X. A direction parallel to the Y-axis is referred to as a second direction Y. A direction parallel to the Z-axis is referred to as a third direction Z. When various elements are viewed parallel to the third direction Z, the appearance is defined as a plan view.

The display device of the present embodiment is an organic electroluminescent display device comprising an organic light emitting diode (OLED) as a display element, and could be mounted on a television, a personal computer, a vehicle-mounted device, a tablet, a smartphone, a mobile phone, etc.

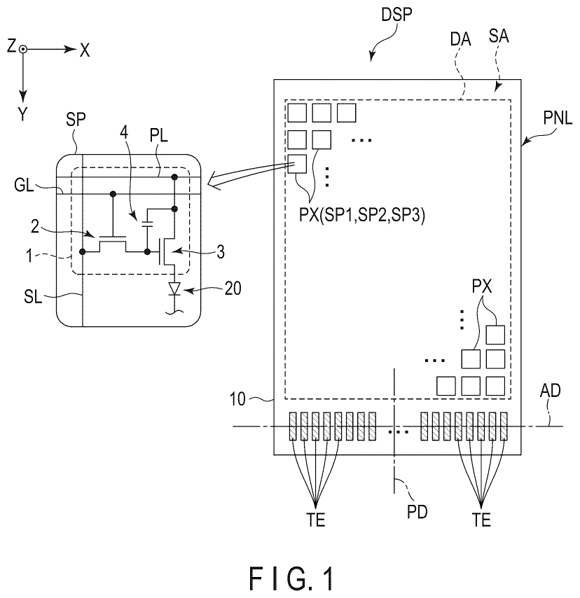

FIG. 1 is a diagram showing a configuration example of a display device DSP.

The display device DSP comprises a display panel PNL comprising a display area DA which displays an image and a surrounding area SA located on an external side relative to the display area DA on an insulating substrate 10. The substrate 10 may be glass or a resinous film having flexibility.

In the embodiment, the substrate 10 is rectangular as seen in plan view. It should be noted that the shape of the substrate 10 in plan view is not limited to a rectangle and may be another shape such as a square, a circle or an oval.

The display area DA comprises a plurality of pixels PX arrayed in matrix in a first direction X and a second direction Y. Each pixel PX includes a plurality of subpixels SP. For example, each pixel PX includes subpixel SP1 which exhibits a first color, subpixel SP2 which exhibits a second color and subpixel SP3 which exhibits a third color. The first color, the second color and the third color are different colors. Each pixel PX may include a subpixel SP which exhibits another color such as white in addition to subpixels SP1, SP2 and SP3 or instead of one of subpixels SP1, SP2 and SP3.

Each subpixel SP comprises a pixel circuit 1 and a display element 20 driven by the pixel circuit 1. The pixel circuit 1 comprises a pixel switch 2, a drive transistor 3 and a capacitor 4. The pixel switch 2 and the drive transistor 3 are, for example, switching elements consisting of thin-film transistors.

The gate electrode of the pixel switch 2 is connected to a scanning line GL. One of the source electrode and drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the anode of the display element 20.

It should be noted that the configuration of the pixel circuit 1 is not limited to the example shown in the figure. For example, the pixel circuit 1 may comprise more thin-film transistors and capacitors.

The display element 20 is an organic light emitting diode (OLED) as a light emitting element, and may be called an organic EL element.

The surrounding area SA comprises a plurality of terminals TE for connecting an IC chip and a flexible printed circuit. The terminals TE are arranged in a single direction. In the example shown in the figure, the terminals TE are arranged in the first direction X. The arrangement direction AD in which the terminals TR are arranged is, for example, a direction parallel to the line segment which passes through the center of each terminal TE. The arrangement direction AD is parallel to the first direction X. A perpendicular direction PD orthogonal to the arrangement direction AD is parallel to the second direction Y.

In the example shown in the figure, each terminal TE extends in the second direction Y. However, the configuration is not limited to this example. For example, some of the terminals TE may extend in an oblique direction.

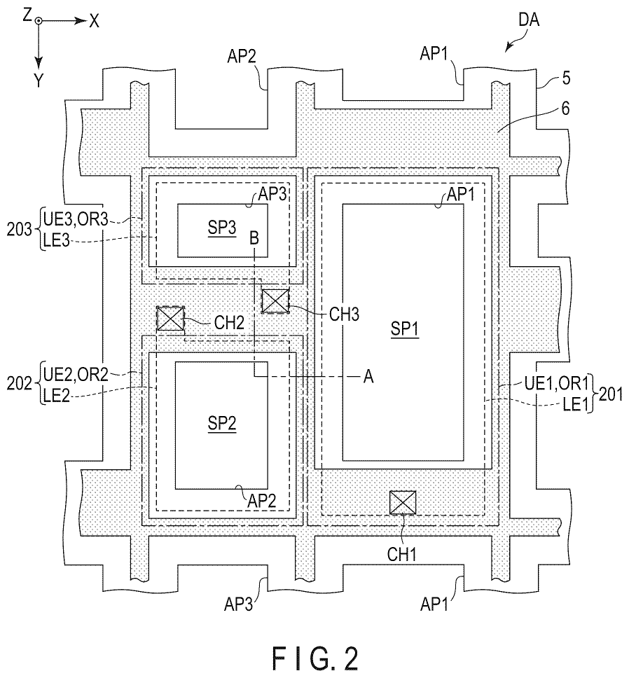

FIG. 2 is a diagram showing an example of the layout of subpixels SP1, SP2 and SP3.

In the example of FIG. 2, subpixels SP2 and SP3 are arranged in the second direction Y. Subpixels SP1 and SP2 are arranged in the first direction X, and subpixels SP1 and SP3 are arranged in the first direction X.

When subpixels SP1, SP2 and SP3 are provided in line with this layout, in the display area DA, a column in which subpixels SP2 and SP3 are alternately provided in the second direction Y and a column in which a plurality of subpixels SP1 are provided in the second direction Y are formed. These columns are alternately arranged in the first direction X.

It should be noted that the layout of subpixels SP1, SP2 and SP3 is not limited to the example of FIG. 2. As another example, subpixels SP1, SP2 and SP3 in each pixel PX may be arranged in order in the first direction X.

An inorganic insulating layer 5 and a partition 6 are provided in the display area DA. The inorganic insulating layer 5 comprises apertures AP1, AP2 and AP3 in subpixels SP1, SP2 and SP3, respectively. The inorganic insulating layer 5 comprising these apertures AP1, AP2 and AP3 may be called a rib.

The partition 6 overlaps the inorganic insulating layer 5 as seen in plan view. The partition 6 is formed into a grating shape surrounding the apertures AP1, AP2 and AP3. In other words, the partition 6 comprises apertures in subpixels SP1, SP2 and SP3 in a manner similar to that of the inorganic insulating layer 5.

Subpixels SP1, SP2 and SP3 comprise display elements 201, 202 and 203, respectively, as the display elements 20.

The display element 201 of subpixel SP1 comprises a lower electrode LE1, an upper electrode UE1 and an organic layer OR1 overlapping the aperture AP1. The peripheral portion of the lower electrode LE1 is covered with the inorganic insulating layer 5. The display element 201 comprising the lower electrode LE1, the organic layer OR1 and the upper electrode UE1 is surrounded by the partition 6 as seen in plan view. The peripheral portion of each of the organic layer OR1 and the upper electrode UE1 overlaps the inorganic insulating layer 5 as seen in plan view. The organic layer OR1 includes a light emitting layer which emits light in, for example, a blue wavelength range.

The display element 202 of subpixel SP2 comprises a lower electrode LE2, an upper electrode UE2 and an organic layer OR2 overlapping the aperture AP2. The peripheral portion of the lower electrode LE2 is covered with the inorganic insulating layer 5. The display element 202 comprising the lower electrode LE2, the organic layer OR2 and the upper electrode UE2 is surrounded by the partition 6 as seen in plan view. The peripheral portion of each of the organic layer OR2 and the upper electrode UE2 overlaps the inorganic insulating layer 5 as seen in plan view. The organic layer OR2 includes a light emitting layer which emits light in, for example, a green wavelength range.

The display element 203 of subpixel SP3 comprises a lower electrode LE3, an upper electrode UE3 and an organic layer OR3 overlapping the aperture AP3. The peripheral portion of the lower electrode LE3 is covered with the inorganic insulating layer 5. The display element 203 comprising the lower electrode LE3, the organic layer OR3 and the upper electrode UE3 is surrounded by the partition 6 as seen in plan view. The peripheral portion of each of the organic layer OR3 and the upper electrode UE3 overlaps the inorganic insulating layer 5 as seen in plan view. The organic layer OR3 includes a light emitting layer which emits light in, for example, a red wavelength range.

In the example of FIG. 2, the outer shapes of the lower electrodes LE1, LE2 and LE3 are shown by dotted lines, and the outer shapes of the organic layers OR1, OR2 and OR3 and the upper electrodes UE1, UE2 and UE3 are shown by alternate long and short dash lines. It should be noted that the outer shape of each of the lower electrodes, organic layers and upper electrodes shown in the figure does not necessarily reflect the accurate shape.

The lower electrodes LE1, LE2 and LE3 correspond to, for example, the anodes of the display elements. The upper electrodes UE1, UE2 and UE3 correspond to the cathodes of the display elements or a common electrode.

The lower electrode LE1 is connected to the pixel circuit 1 (see FIG. 1) of subpixel SP1 through a contact hole CH1. The lower electrode LE2 is connected to the pixel circuit 1 of subpixel SP2 through a contact hole CH2. The lower electrode LE3 is connected to the pixel circuit 1 of subpixel SP3 through a contact hole CH3.

In the example of FIG. 2, the area of the aperture AP1, the area of the aperture AP2 and the area of the aperture AP3 are different from each other. The area of the aperture AP1 is greater than that of the aperture AP2, and the area of the aperture AP2 is greater than that of the aperture AP3. In other words, the area of the lower electrode LE1 exposed from the aperture AP1 is greater than that of the lower electrode LE2 exposed from the aperture AP2. The area of the lower electrode LE2 exposed from the aperture AP2 is greater than that of the lower electrode LE3 exposed from the aperture AP3.

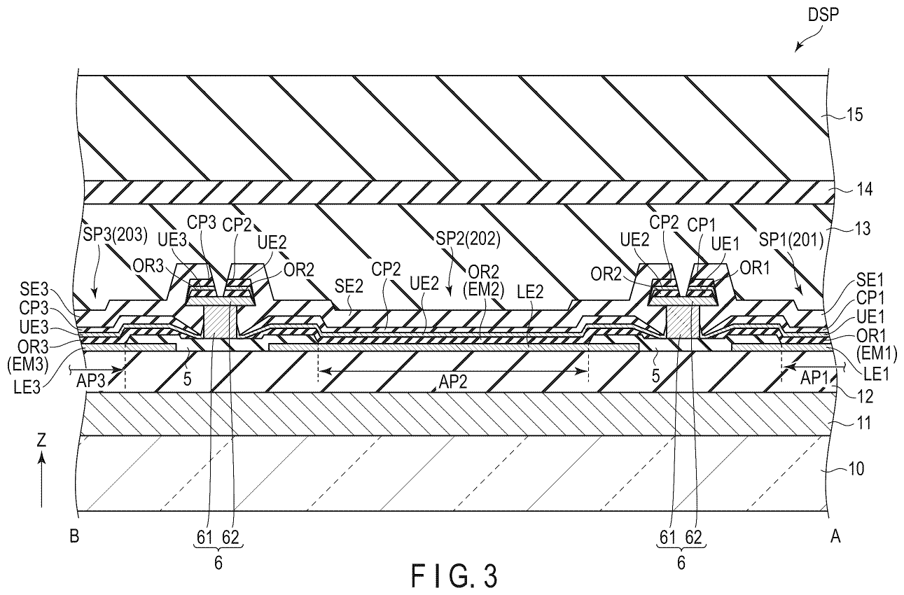

FIG. 3 is a schematic cross-sectional view of the display device DSP along the A-B line of FIG. 2.

A circuit layer 11 is provided on the substrate 10. The circuit layer 11 includes various circuits such as the pixel circuit 1 shown in FIG. 1 and various lines such as the scanning line GL, the signal line SL and the power line PL. The circuit layer 11 is covered with an insulating layer 12. The insulating layer 12 is an organic insulating layer which planarizes the irregularities formed by the circuit layer 11.

The lower electrodes LE1, LE2 and LE3 are provided on the insulating layer 12 and are spaced apart from each other. The inorganic insulating layer 5 is provided on the insulating layer 12 and the lower electrodes LE1, LE2 and LE3. The aperture AP1 of the inorganic insulating layer 5 overlaps the lower electrode LE1. The aperture AP2 overlaps the lower electrode LE2. The aperture AP3 overlaps the lower electrode LE3. The peripheral portions of the lower electrodes LE1, LE2 and LE3 are covered with the inorganic insulating layer 5. The insulating layer 12 is covered with the inorganic insulating layer 5 between, of the lower electrodes LE1, LE2 and LE3, the lower electrodes which are adjacent to each other. The lower electrodes LE1, LE2 and LE3 are connected to the pixel circuits 1 of subpixels SP1, SP2 and SP3, respectively, through the contact holes provided in the insulating layer 12. It should be noted that, although the contact holes of the insulating layer 12 are omitted in FIG. 3, the contact holes correspond to the contact holes CH1, CH2 and CH3 of FIG. 2.

The partition 6 includes a conductive lower portion (stem) 61 provided on the inorganic insulating layer 5 and an upper portion (cap) 62 provided on the lower portion 61. The lower portion 61 of the partition 6 shown on the right side of the figure is located between the aperture AP1 and the aperture AP2. The lower portion 61 of the partition 6 shown on the left side of the figure is located between the aperture AP2 and the aperture AP3. The upper portion 62 has a width greater than that of the lower portion 61. The both end portions of the upper portion 62 protrude relative to the side surfaces of the lower portion 61. This shape of the partition 6 is called an overhang shape.

The organic layer OR1 is in contact with the lower electrode LE1 through the aperture AP1 and covers the lower electrode LE1 exposed from the aperture AP1. The peripheral portion of the organic layer OR1 is located on the inorganic insulating layer 5. The upper electrode UE1 covers the organic layer OR1 and is in contact with the lower portion 61.

The organic layer OR2 is in contact with the lower electrode LE2 through the aperture AP2 and covers the lower electrode LE2 exposed from the aperture AP2. The peripheral portion of the organic layer OR2 is located on the inorganic insulating layer 5. The upper electrode UE2 covers the organic layer OR2 and is in contact with the lower portion 61.

The organic layer OR3 is in contact with the lower electrode LE3 through the aperture AP3 and covers the lower electrode LE3 exposed from the aperture AP3. The peripheral portion of the organic layer OR3 is located on the inorganic insulating layer 5. The upper electrode UE3 covers the organic layer OR3 and is in contact with the lower portion 61.

In the example of FIG. 3, subpixel SP1 comprises a cap layer CP1 and a sealing layer SE1. Subpixel SP2 comprises a cap layer CP2 and a sealing layer SE2. Subpixel SP3 comprises a cap layer CP3 and a sealing layer SE3. The cap layers CP1, CP2 and CP3 function as optical adjustment layers which improve the extraction efficiency of the light emitted from the organic layers OR1, OR2 and OR3, respectively.

The cap layer CP1 is provided on the upper electrode UE1.

The cap layer CP2 is provided on the upper electrode UE2.

The cap layer CP3 is provided on the upper electrode UE3.

The sealing layer SE1 is provided on the cap layer CP1, is in contact with the partition 6 and continuously covers each member of subpixel SP1.

The sealing layer SE2 is provided on the cap layer CP2, is in contact with the partition 6 and continuously covers each member of subpixel SP2.

The sealing layer SE3 is provided on the cap layer CP3, is in contact with the partition 6 and continuously covers each member of subpixel SP3.

In the example of FIG. 3, each of the organic layer OR1, the upper electrode UE1 and the cap layer CP1 is partly located on the partition 6 around subpixel SP1. These portions are spaced apart from, of the organic layer OR1, the upper electrode UE1 and the cap layer CP1, the portions located in the aperture AP1 (the portions constituting the display element 201).

Similarly, each of the organic layer OR2, the upper electrode UE2 and the cap layer CP2 is partly located on the partition 6 around subpixel SP2. These portions are spaced apart from, of the organic layer OR2, the upper electrode UE2 and the cap layer CP2, the portions located in the aperture AP2 (the portions constituting the display element 202).

Similarly, each of the organic layer OR3, the upper electrode UE3 and the cap layer CP3 is partly located on the partition 6 around subpixel SP3. These portions are spaced apart from, of the organic layer OR3, the upper electrode UE3 and the cap layer CP3, the portions located in the aperture AP3 (the portions constituting the display element 203).

The end portions of the sealing layers SE1, SE2 and SE3 are located above the partition 6. In the example of FIG. 3, the end portions of the sealing layers SE1 and SE2 located above the partition 6 between subpixels SP1 and SP2 are spaced apart from each other. The end portions of the sealing layers SE2 and SE3 located above the partition 6 between subpixels SP2 and SP3 are spaced apart from each other.

The sealing layers SE1, SE2 and SE3 are covered with a resin layer 13. The resin layer 13 is covered with a sealing layer 14. The sealing layer 14 is covered with a resin layer 15.

Each of the inorganic insulating layer 5, the sealing layers SE1, SE2 and SE3 and the sealing layer 14 is formed of, for example, an inorganic insulating material such as silicon nitride (SiNx), silicon oxide (SiOx), silicon oxynitride (SiON) or aluminum oxide (Al₂O₃).

The lower portion 61 of the partition 6 is formed of a conductive material and is electrically connected to the upper electrodes UE1, UE2 and UE3. The upper portion 62 of the partition 6 is formed of, for example, a conductive material. However, the upper portion 62 may be formed of an insulating material. The lower portion 61 is formed of a material which is different from that of the upper portion 62.

For example, each of the lower electrodes LE1, LE2 and LE3 is a multilayer body including a transparent electrode formed of an oxide conductive material such as indium tin oxide (ITO) and a metal electrode formed of a metal material such as silver.

The organic layer OR1 includes a light emitting layer EM1. The organic layer OR2 includes a light emitting layer EM2. The organic layer OR3 includes a light emitting layer EM3. The light emitting layer EM1, the light emitting layer EM2 and the light emitting layer EM3 are formed of materials which are different from each other. For example, the light emitting layer EM1 is formed of a material which emits light in a blue wavelength range. The light emitting layer EM2 is formed of a material which emits light in a green wavelength range. The light emitting layer EM3 is formed of a material which emits light in a red wavelength range.

Each of the organic layers OR1, OR2 and OR3 includes a plurality of functional layers such as a hole injection layer, a hole transport layer, an electron blocking layer, a hole blocking layer, an electron transport layer and an electron injection layer.

Each of the upper electrodes UE1, UE2 and UE3 is formed of, for example, a metal material such as an alloy of magnesium and silver (MgAg).

Each of the cap layers CP1, CP2 and CP3 is a multilayer body consisting of a plurality of thin films. All of the thin films are transparent and have refractive indices different from each other.

The circuit layer 11, insulating layer 12 and inorganic insulating layer 5 shown in FIG. 3 are provided over the display area DA and the surrounding area SA.

Now, this specification explains a mother substrate 100 for a display device (hereinafter, simply referred to as a mother substrate 100) for manufacturing a plurality of display devices DSP in a lump.

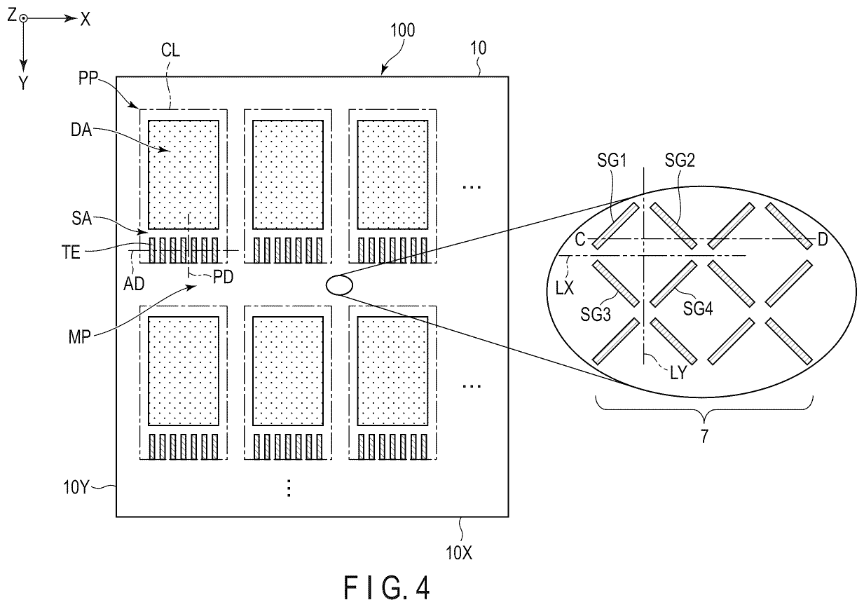

FIG. 4 is a plan view showing an example of the mother substrate 100.

The mother substrate 100 comprises a plurality of panel portions PP and a margin portion MP provided on an external side relative to these panel portions PP on a large substrate 10. The large substrate 10 is formed into a rectangular shape and comprises a linear first side 10X and a linear second side 10Y. The first side 10X extends in the first direction X. The second side 10Y extends in the second direction Y.

The panel portions PP are arrayed in matrix in the first direction X and the second direction Y. The panel portions PP are extracted by dividing the mother substrate 100 along cut lines CL. Each of the extracted panel portions PP corresponds to the display panel PNL shown in FIG. 1. Each cut line CL shown by a one-dot chain line in FIG. 4 corresponds to the outer shape of the display panel PNL. Each panel portion PP comprises a display area DA and a surrounding area SA in which terminals TE and the like are provided.

As shown in the enlarged view of FIG. 4, a partition 7 is provided in the margin portion MP. The partition 7 has a shape which is not orthogonal to the first direction X which is the extension direction of the first side 10X, or the arrangement direction AD of the terminals TE. Further, the partition 7 has a shape which is not orthogonal to the second direction Y which is the extension direction of the second side 10Y, the perpendicular direction PD or the cut lines CL (the outer shape of each display panel).

In the example of FIG. 4, the partition 7 comprises a plurality of segments SG1, SG2, SG3, . . . , each formed into a linear shape. Each of the segments SG1, SG2, SG3, . . . , extends in an oblique direction intersecting with the first direction X and the second direction Y. Moreover, the segments SG1 and SG2 arranged in the first direction X extend in directions different from each other. The segments SG1 and SG3 arranged in the second direction Y also extend in directions different from each other.

When this specification focuses attention on four segments SG1, SG2, SG3 and SG4 in the figure, the segments SG1 and SG2 and the segments SG3 and SG4 are line symmetrical, respectively, with respect to straight line LX extending in the first direction X. Further, the segments SG1 and SG3 and the segments SG2 and SG4 are line symmetrical, respectively, with respect to straight line LY extending in the second direction Y. The segment SG1 and the segment SG4 are parallel to each other. The segment SG2 and the segment SG3 are parallel to each other.

It should be noted that a plurality of segments arranged in the first direction X may be connected to each other, and a plurality of segments arranged in the second direction Y may be connected to each other.

The partition 7 may be provided in the surrounding area SA of each panel portion PP in addition to the margin portion MP.

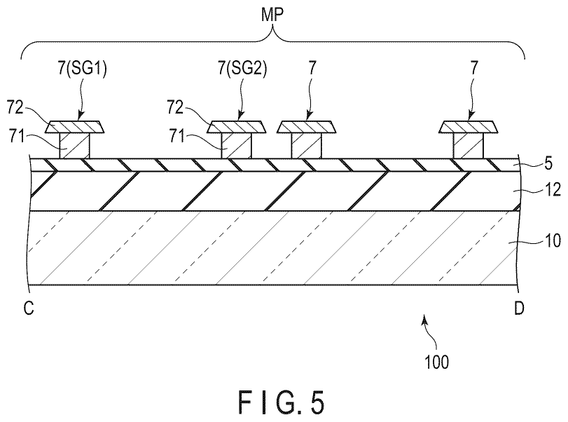

FIG. 5 is a cross-sectional view of the mother substrate 100 along the C-D line of FIG. 4.

In the example shown in the figure, the insulating layer 12 and the inorganic insulating layer 5 extend to the margin portion MP.

The partition 7 includes a lower portion 71 provided on the inorganic insulating layer 5 and an upper portion 72 provided on the lower portion 71. The upper portion 72 has a width which is greater than that of the lower portion 71. The both end portions of the upper portion 72 protrude relative to the side surfaces of the lower portion 71. Thus, the partition 7 has an overhang shape similar to that of the partition 6 shown in FIG. 3. The partition 7 can be formed in the same process as the partition 6. In this case, the lower portion 71 is formed of the same material as the lower portion 61. The upper portion 72 is formed of the same material as the upper portion 62.

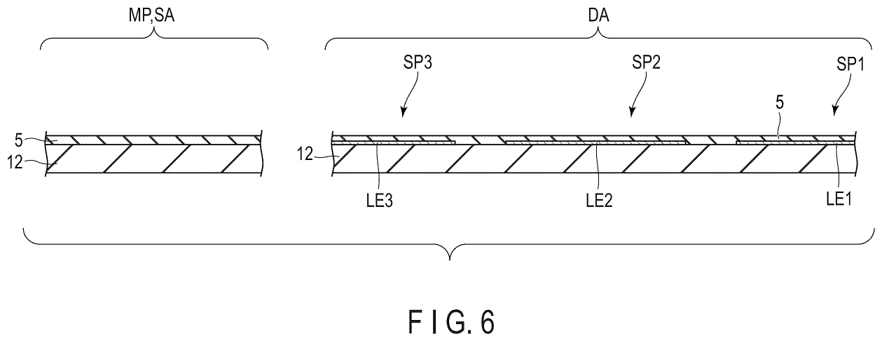

Now, this specification explains the manufacturing method of the display device DSP with reference to FIG. 6 to FIG. 17. In FIG. 6 to FIG. 8 and FIG. 11 to FIG. 17, the illustration of the lower side of the insulating layer 12 is omitted. In the following descriptions, this specification explains a case where the partition 7 is formed in the margin portion MP and the surrounding area SA. However, the partition 7 may not be formed in the surrounding area SA.

First, as shown in FIG. 6, the lower electrode LE1 of subpixel SP1, the lower electrode LE2 of subpixel SP2 and the lower electrode LE3 of subpixel SP3 are formed on the insulating layer 12 in the display area DA. Subsequently, the inorganic insulating layer 5 is formed over the display area DA, the surrounding area SA and the margin portion MP. In the display area DA, the lower electrodes LE1, LE2 and LE3 are covered with the inorganic insulating layer 5.

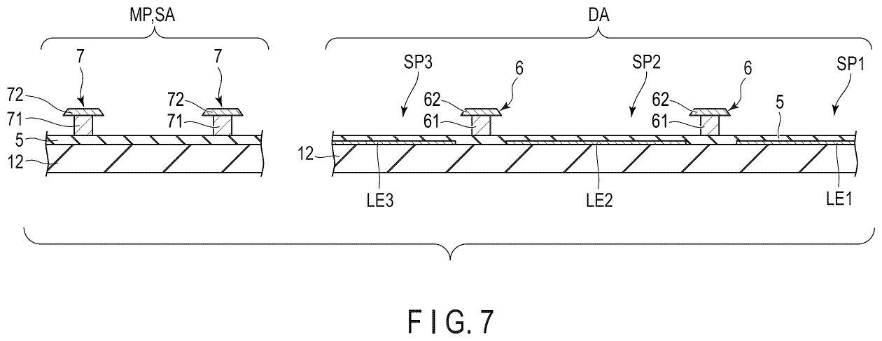

Subsequently, as shown in FIG. 7, in the display area DA, the partition 6 which comprises the lower portion 61 located on the inorganic insulating layer 5 and the upper portion 62 located on the lower portion 61 is formed. At the same time, in the surrounding area SA and the margin portion MP, the partition 7 which comprises the lower portion 71 located on the inorganic insulating layer 5 and the upper portion 72 located on the lower portion 71 is formed.

These partition 6 and partition 7 are formed through, for example, the following process. Specifically, a first layer (conductive layer) is formed on the inorganic insulating layer 5. A second layer is formed on the first layer. The upper portion 62 and the upper portion 72 are formed by patterning the second layer. Subsequently, the lower portion 61 and the lower portion 71 are formed by patterning the first layer.

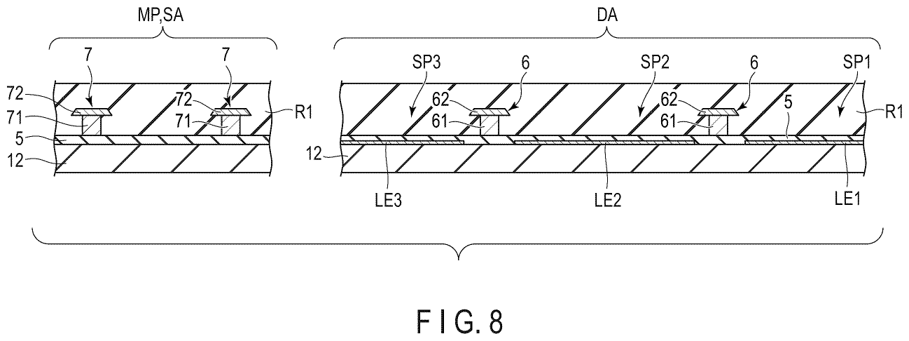

Subsequently, as shown in FIG. 8, a resist R1 is applied over the display area DA, the surrounding area SA and the margin portion MP. The resist R1 covers the inorganic insulating layer 5, the partition 6 and the partition 7.

Now, this specification explains a process for applying the resist R1.

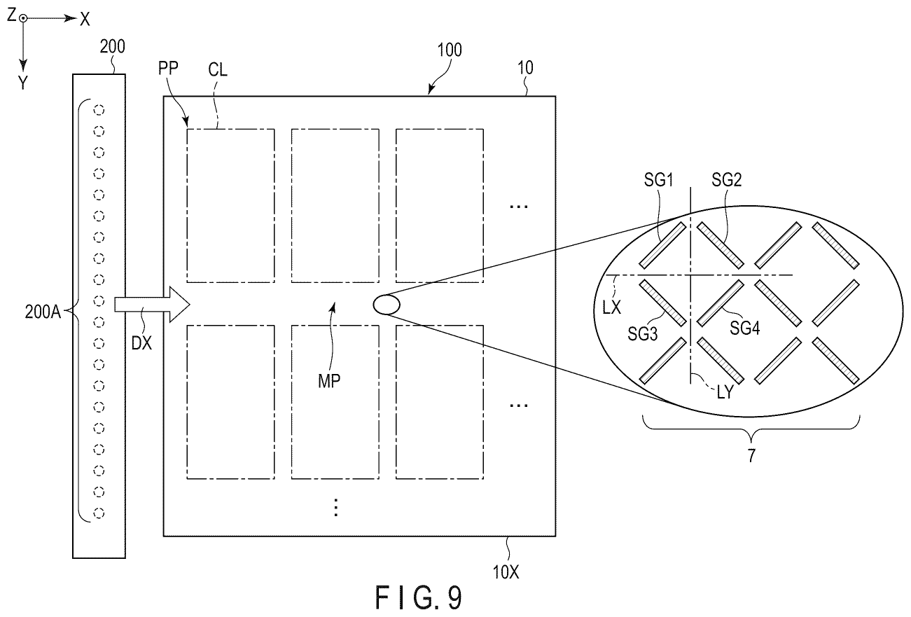

In the example shown in FIG. 9, an application device 200 for applying the resist R1 comprises a plurality of nozzles 200A arranged in the second direction Y. The application device 200 moves in the first direction X while discharging an organic material toward the mother substrate 100. Thus, application direction DX of the resist R1 by the application device 200 is parallel to the first side 10X. It should be noted that the mother substrate 100 may move in the first direction X relative to the fixed application device 200.

As described above, the partition 7 is not orthogonal to the extension direction of the first side 10X or is not orthogonal to application direction DX. Thus, the applied resist R1 is not dammed up by the partition 7 and expands while making contact with the partition 7. This configuration can prevent problems such as the formation of an undesired cavity in the resist R1 and the formation of streaky non-uniformity in the resist R1. In other words, as shown in FIG. 8, the area which should be protected in etching which is performed later can be assuredly covered with the resist R1. In this manner, the reduction in reliability can be prevented.

Now, this specification explains another process for applying the resist R1.

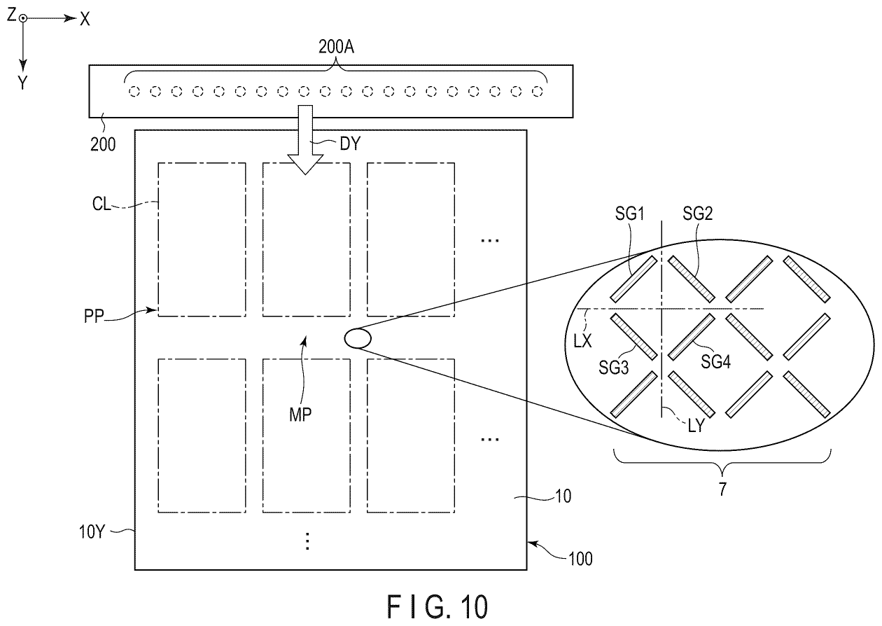

In the example shown in FIG. 10, the application device 200 for applying the resist R1 comprises a plurality of nozzles 200A arranged in the first direction X. The application device 200 moves in the second direction Y while discharging an organic material toward the mother substrate 100. Thus, application direction DY of the resist R1 by the application device 200 is parallel to the second side 10Y. It should be noted that the mother substrate 100 may move in the second direction Y relative to the fixed application device 200.

As described above, the partition 7 is not orthogonal to the extension direction of the second side 10Y or is not orthogonal to application direction DY. Thus, effects similar to those explained with reference to FIG. 9 are obtained.

As described above, the segments SG1, SG2, SG3 and SG4 of the partition 7 shown in the drawings are formed into a line symmetrical shape with respect to straight line LX and straight line LY. Thus, in the shape of the partition 7 shown in the drawings, regarding how the resist R1 expands, there is no difference between a case where application direction DX shown in FIG. 9 is applied and a case where application direction DY shown in FIG. 10 is applied. Therefore, the shape of the partition 7 shown in the drawings is desirable.

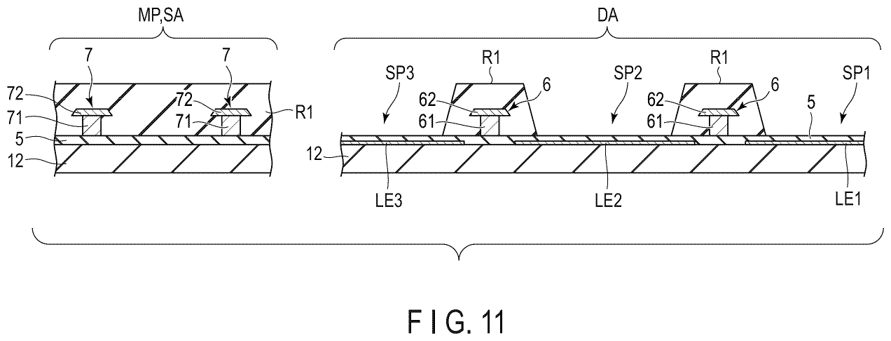

Subsequently, as shown in FIG. 11, the resist R1 is patterned into a predetermined shape. At this time, in the example shown in the figure, in the surrounding area SA and the margin portion MP, the resist R1 covers the inorganic insulating layer 5 and the partition 7. In the display area DA, the resist R1 covers the partition 6, and part of the inorganic insulating layer 5 (in other words, portions which overlap the lower electrodes LE1, LE2 and LE3) is (are) exposed from the resist R1.

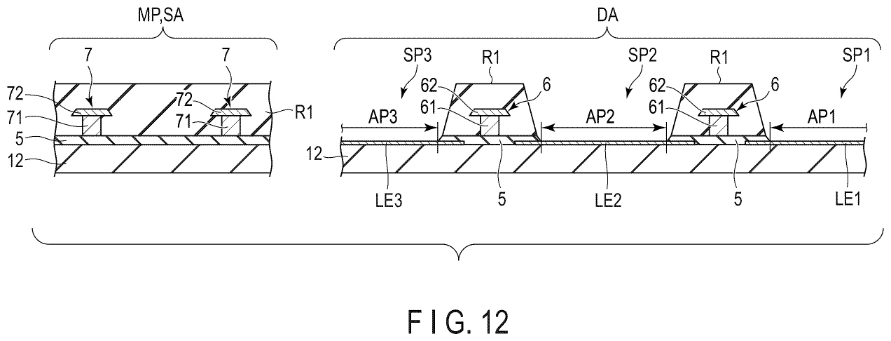

Subsequently, as shown in FIG. 12, etching is performed using the resist R1 as a mask. By this process, the apertures AP1, AP2 and AP3 are formed in the inorganic insulating layer 5 in the display area DA. The aperture AP1 overlaps the lower electrode LE1 of subpixel SP1. The aperture AP2 overlaps the lower electrode LE2 of subpixel SP2. The aperture AP3 overlaps the lower electrode LE3 of subpixel SP3.

Subsequently, the resist R1 is removed.

As described above, the inorganic insulating layer 5 and the partition 7 are assuredly covered with the resist R1 in the surrounding area SA and the margin portion MP. Thus, the inorganic insulating layer 5 or the partition 7 is not substantially damaged by etching.

Subsequently, the display element 201 is formed. Regarding the formation process of the display element 201, the illustrations of the surrounding area SA and the margin portion MP are omitted.

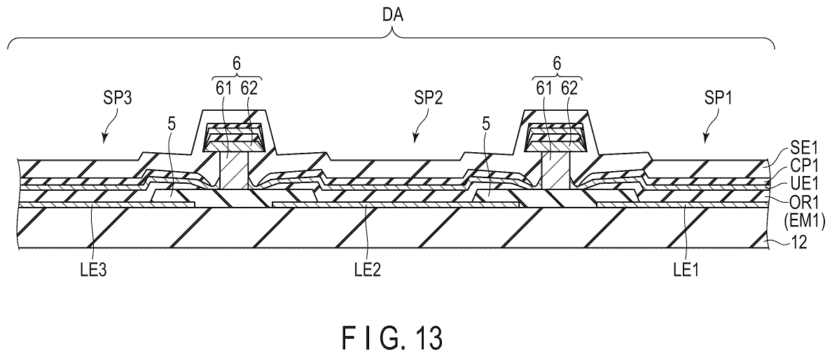

First, as shown in FIG. 13, the organic layer OR1 is formed by depositing the materials for forming the hole injection layer, the hole transport layer, the electron blocking layer, the light emitting layer (EM1), the hole blocking layer, the electron transport layer, the electron injection layer, etc., on the lower electrode LE1 in series using the partition 6 as a mask.

Subsequently, the upper electrode UE1 is formed by depositing a mixture of magnesium and silver on the organic layer OR1 using the partition 6 as a mask. The upper electrode UE1 covers the organic layer OR1 and is in contact with the lower portion 61.

Subsequently, the cap layer CP1 is formed by depositing a high-refractive material and a low-refractive material in series on the upper electrode UE1 using the partition 6 as a mask.

These organic layer OR1, upper electrode UE1 and cap layer CP1 are successively formed in a state where a vacuum environment is maintained.

Subsequently, the sealing layer SE1 is formed so as to continuously cover the cap layer CP1 and the partition 6.

The organic layer OR1, the upper electrode UE1, the cap layer CP1 and the sealing layer SE1 are formed in at least the entire display area DA and are provided in subpixels SP2 and SP3 as well as subpixel SP1. The organic layer OR1, the upper electrode UE1 and the cap layer CP1 are divided by the partition 6 having an overhang shape.

The materials which are emitted from an evaporation source when the organic layer OR1, the upper electrode UE1 and the cap layer CP1 are formed by vapor deposition are blocked by the upper portion 62. Thus, each of the organic layer OR1, the upper electrode UE1 and the cap layer CP1 is partly stacked on the upper portion 62. The organic layer OR1, upper electrode UE1 and cap layer CP1 located on the upper portion 62 are spaced apart from the organic layer OR1, upper electrode UE1 and cap layer CP1 located immediately above the lower electrode LE1.

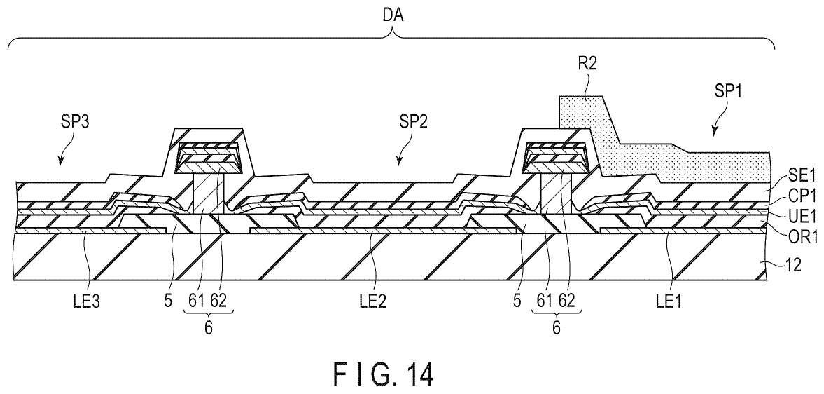

Subsequently, as shown in FIG. 14, a resist R2 patterned into a predetermined shape is formed on the sealing layer SE1. The resist R2 overlaps subpixel SP1 and part of the partition 6 around subpixel SP1.

Although not described in detail, when the resist R2 is formed, the application direction of the resist R2 is set in a manner similar to that of the resist R1. Even if application direction DX shown in FIG. 9 or application direction DY shown in FIG. 10 is selected, the expansion of the resist R2 is not blocked by the partition 7 in the surrounding area SA or the margin portion MP. This configuration can prevent the resist R2 from undesirably having a defective portion.

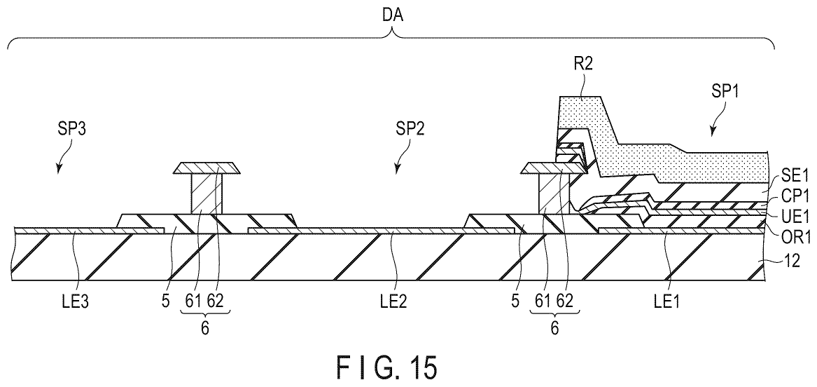

Subsequently, as shown in FIG. 15, the sealing layer SE1, cap layer CP1, upper electrode UE1 and organic layer OR1 exposed from the resist R2 are removed in series by performing etching using the resist R2 as a mask. In this manner, the lower electrode LE2 of subpixel SP2 and the lower electrode LE3 of subpixel SP3 are exposed.

Subsequently, the resist R2 is removed. By this process, the display element 201 is formed in subpixel SP1.

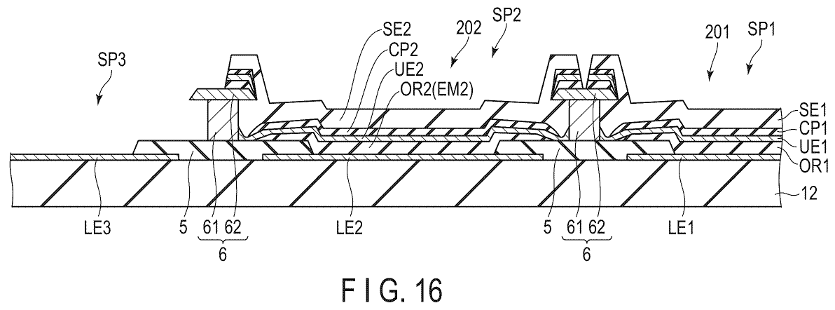

Subsequently, as shown in FIG. 16, the display element 202 is formed. The procedure of forming the display element 202 is similar to that of forming the display element 201. Specifically, the organic layer OR2 including the light emitting layer EM2, the upper electrode UE2, the cap layer CP2 and the sealing layer SE2 are formed in order on the lower electrode LE2. Subsequently, a resist is formed on the sealing layer SE2. The sealing layer SE2, the cap layer CP2, the upper electrode UE2 and the organic layer OR2 are patterned in series by etching using the resist as a mask. After this patterning, the resist is removed. In this manner, the display element 202 is formed in subpixel SP2, and the lower electrode LE3 of subpixel SP3 is exposed.

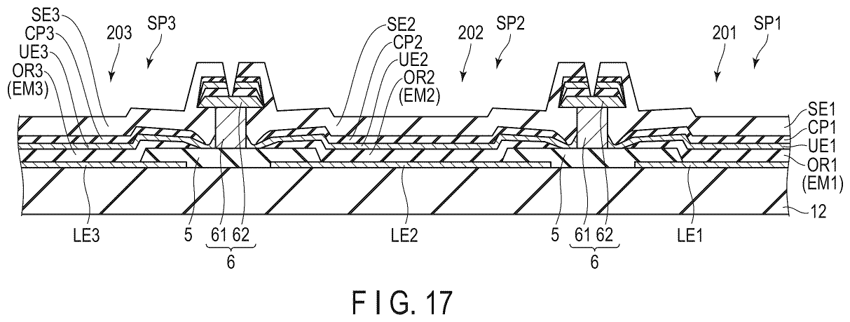

Subsequently, as shown in FIG. 17, the display element 203 is formed. The procedure of forming the display element 203 is similar to that of forming the display element 201. Specifically, the organic layer OR3 including the light emitting layer EM3, the upper electrode UE3, the cap layer CP3 and the sealing layer SE3 are formed in order on the lower electrode LE3. Subsequently, a resist is formed on the sealing layer SE3. The sealing layer SE3, the cap layer CP3, the upper electrode UE3 and the organic layer OR3 are patterned in series by etching using the resist as a mask. After this patterning, the resist is removed. By this process, the display element 203 is formed in subpixel SP3.

Subsequently, the resin layer 13, sealing layer 14 and resin layer 15 shown in FIG. 3 are formed in order. By this process, the display device DSP is completed.

In the manufacturing process described above, this specification assumes a case where the display element 201 is formed firstly, and the display element 202 is formed secondly, and the display element 203 is formed lastly. However, the formation order of the display elements 201, 202 and 203 is not limited to this example.

Now, this specification explains other configuration examples of the partition 7.

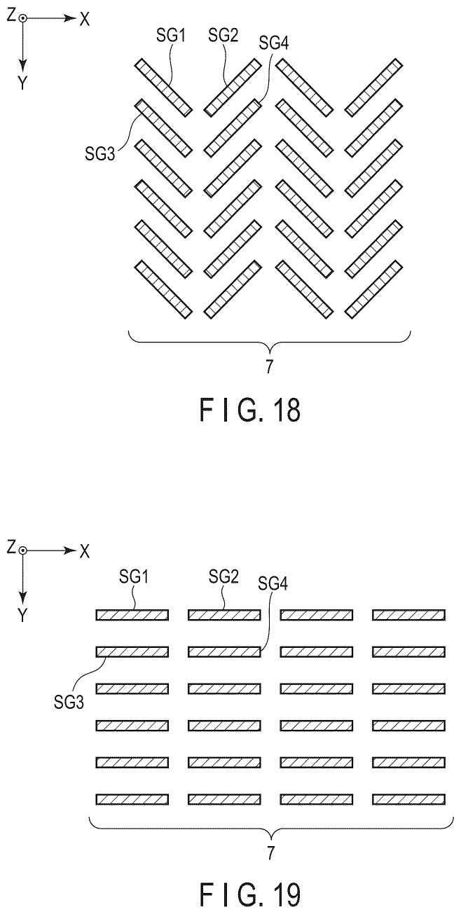

FIG. 18 is a diagram showing another configuration example of the partition 7.

The partition 7 comprises a plurality of segments SG1, SG2, SG3, . . . , each formed into a linear shape. Each of the segments SG1, SG2, SG3, . . . , extends in an oblique direction intersecting with the first direction X and the second direction Y. Moreover, the segments SG1 and SG2 arranged in the first direction X extend in directions different from each other. The segments SG1 and SG3 arranged in the second direction Y are parallel to each other.

In this configuration example, similarly, even if application direction DX or application direction DY is selected at the time of the formation of the resist R1, the expansion of the resist R1 is not blocked by the partition 7. This configuration can prevent the resist R1 from undesirably having a defective portion.

FIG. 19 is a diagram showing another configuration example of the partition 7.

The partition 7 comprises a plurality of segments SG1, SG2, SG3, . . . , each formed into a linear shape. Each of the segments SG1, SG2, SG3, . . . , extends in the first direction X.

In this configuration example, in a case where application direction DX is selected at the time of the formation of the resist R1, the expansion of the resist R1 is not blocked by the partition 7. This configuration can prevent the resist R1 from undesirably having a defective portion.

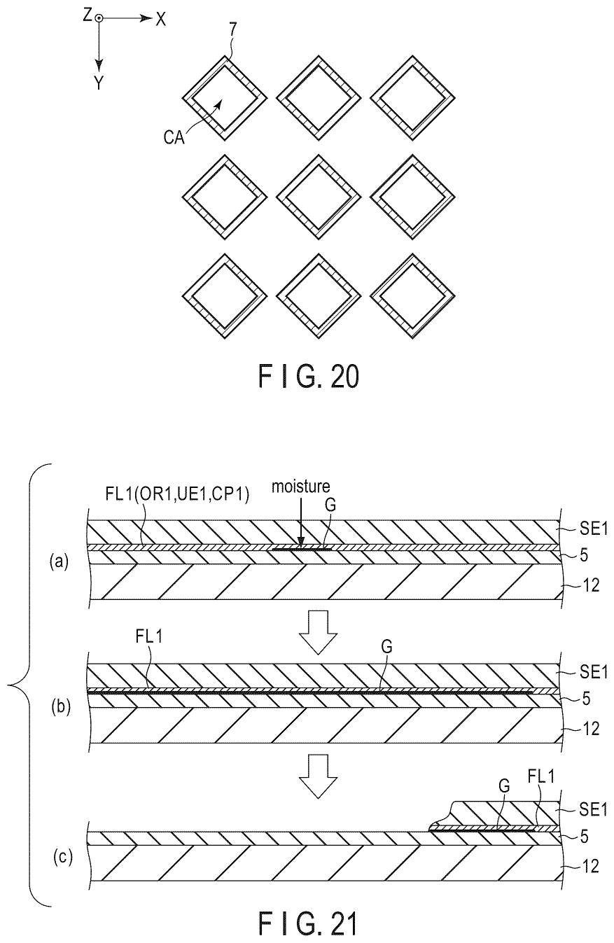

FIG. 20 is a diagram showing another configuration example of the partition 7.

The configuration example shown in FIG. 20 is different from the above configuration examples in respect that the partition 7 is formed into an independent loop shape. A closed area CA is formed inside the partition 7. In the example shown in the figure, the partition 7 is formed into a rectangular shape as an example of polygonal shapes, and further, each of the four sides of the rectangle extends in an oblique direction intersecting with the first direction X and the second direction Y.

In other words, in a manner similar to that of the example explained with reference to FIG. 4, the partition 7 has a shape which is not orthogonal to the first direction X which is the extension direction of the first side 10X, or the arrangement direction AD of the terminals TE. Further, the partition 7 has a shape which is not orthogonal to the second direction Y which is the extension direction of the second side 10Y, the perpendicular direction PD or the cut lines CL.

In this manner, in this configuration example, similarly, even if application direction DX or application direction DY is selected at the time of the formation of the resist R1, the expansion of the resist R1 is not blocked by the partition 7. This configuration can prevent the resist R1 from undesirably having a defective portion.

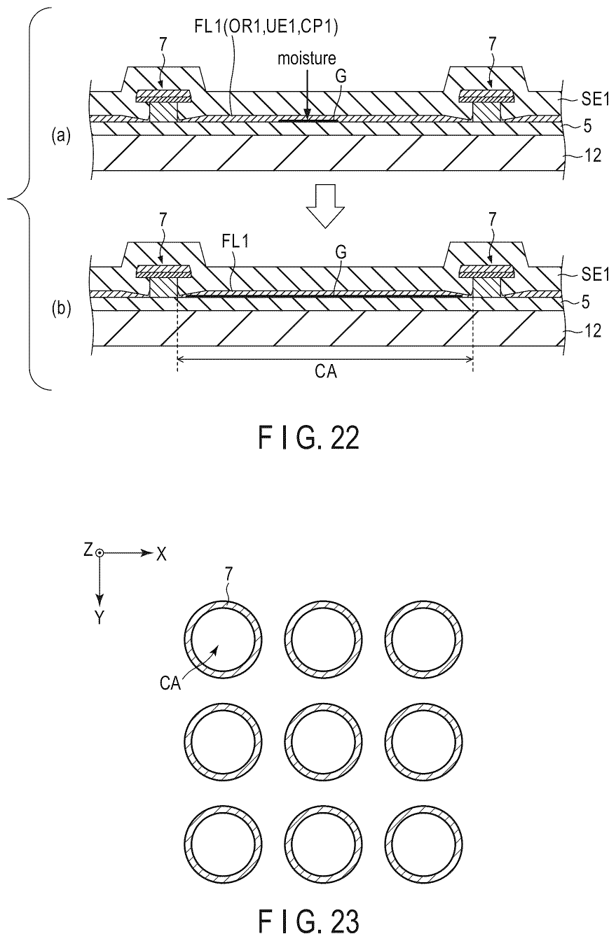

In addition, as the partition 7 forms the closed area CA, the removal of a multilayer film is prevented. The effects of this configuration are explained below with reference to FIG. 21 and FIG. 22. Here, the multilayer film includes, for example, the organic layer OR1, upper electrode UE1 and cap layer CP1 formed by the vapor deposition explained with reference to FIG. 13.

FIG. 21 is a cross-sectional view for explaining a comparative example which does not comprise the partition 7.

In the figure, (a) shows a state in which moisture enters the multilayer film FL1 after the formation of the multilayer film FL1 and the sealing layer SE1. To pattern the multilayer film FL1 and the sealing layer SE1, wet processing such as the development process of the resist R2 and washing treatment is performed. At this time, when a tiny pinhole is formed in the sealing layer SE1, moisture easily enters the multilayer film FL1 in wet processing. If the moisture which entered the multilayer film FL1 reaches the interface between the organic layer OR1 and the inorganic insulating layer 5, the organic layer OR1 is raised from the surface of the inorganic insulating layer 5, and a cavity G could be generated.

In the figure, (b) shows a state in which the moisture is spread in the organic layer OR1 and the cavity G is expanded. In connection with the expansion of the cavity G, the adhesion between the multilayer film FL1 and the inorganic insulating layer 5 is decreased. The unstable multilayer film FL1 is in a state where it is easily removed with the sealing layer SE1.

In the figure, (c) shows a state in which the multilayer film FL1 and the sealing layer SE1 are partly removed. In a case where the multilayer film FL1 is formed in a large area, a large part of the multilayer film FL1 could be removed based on removal of a part of the multilayer film FL1. The removed multilayer film FL1 and sealing layer SE1 float inside the manufacturing device as foreign substances and could be a contaminant source. If the floating foreign substances are attached to the mother substrate, various defects could be caused.

FIG. 22 is a cross-sectional view for explaining the embodiment which comprises the partition 7.

In the figure, (a) shows a state in which moisture enters the multilayer film FL1 after the formation of the multilayer film FL1 and the sealing layer SE1. A cavity G is generated between the multilayer film FL1 and the inorganic insulating layer 5 because of the entrance of moisture. Each of the organic layer OR1, upper electrode UE1 and cap layer CP1 constituting the multilayer film FL1 is formed by performing vapor deposition using the partition 7 as a mask. Thus, the multilayer film FL1 provided on the inorganic insulating layer 5 is divided from the multilayer film FL1 provided on the partition 7.

In the figure, (b) shows a state in which the cavity G is expanded. As described above, as the multilayer film FL1 is divided by the partition 7, the expansion of the cavity G is prevented. Specifically, as shown in the figure, when a cavity G is generated in the closed area CA, the expansion of the cavity G is limited to the inside of the closed area CA. When a cavity G is generated on the partition 7, the expansion of the cavity G is limited to the upper side of the partition 7. In this manner, the expansion of the cavity G is prevented, and further, the raised multilayer film FL1 is pressed down by the sealing layer SE1. Thus, the removal of the multilayer film FL1 and the sealing layer SE1 is prevented. This configuration prevents the contamination of the manufacturing device and the generation of undesired foreign substances. In this manner, the reduction in reliability is prevented.

FIG. 23 is a diagram showing another configuration example of the partition 7.

The configuration example shown in FIG. 23 is different from that shown in FIG. 20 in respect that the partition 7 is formed into a circular shape. A closed area CA is formed inside the partition 7.

In other words, the partition 7 has a shape which is not orthogonal to the first direction X which is the extension direction of the first side 10X, or the arrangement direction AD of the terminals TE. Further, the partition 7 has a shape which is not orthogonal to the second direction Y which is the extension direction of the second side 10Y, the perpendicular direction PD or the cut lines CL.

In this configuration example, effects similar to those of the configuration example shown in FIG. 20 are obtained.

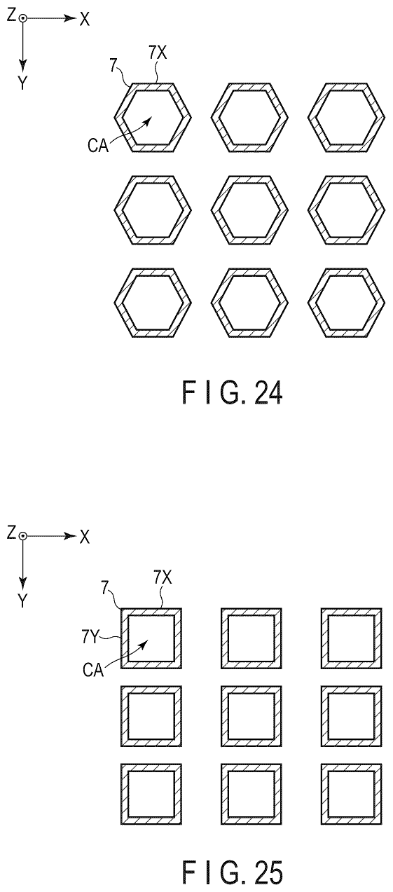

FIG. 24 is a diagram showing another configuration example of the partition 7.

The configuration example shown in FIG. 24 is different from that shown in FIG. 20 in respect that the partition 7 is formed into a hexagonal shape as an example of polygonal shapes. A closed area CA is formed inside the partition 7. In the example shown in the figure, the partition 7 includes sides 7X parallel to the first direction X. Each of the other sides extends in an oblique direction intersecting with the first direction X and the second direction Y.

In other words, the partition 7 has a shape which is not orthogonal to the first direction X which is the extension direction of the first side 10X, or the arrangement direction AD of the terminals TE.

Thus, in this configuration example, in a case where application direction DX is selected at the time of the formation of the resist R1, the expansion of the resist R1 is not blocked by the partition 7. This configuration can prevent the resist R1 from undesirably having a defective portion.

In addition, as the partition 7 forms the closed area CA, the removal of the multilayer film is prevented.

FIG. 25 is a diagram showing another configuration example of the partition 7.

The configuration example shown in FIG. 25 is different from that shown in FIG. 20 in respect that the partition 7 is formed into a rectangular shape including sides 7X parallel to the first direction X and sides 7Y parallel to the second direction Y.

In this configuration example, as the partition 7 forms the closed area CA, the removal of the multilayer film is prevented.

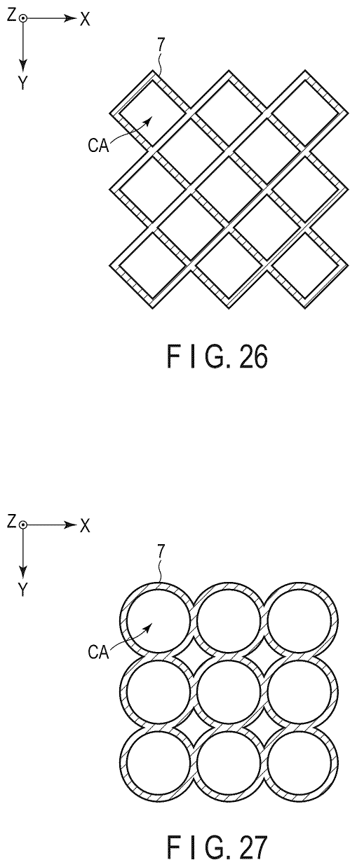

FIG. 26 is a diagram showing another configuration example of the partition 7.

The configuration example shown in FIG. 26 is different from the above configuration examples in respect that the partition 7 is formed into a grating shape. A closed area CA is formed inside the partition 7. In the example shown in the figure, each closed area CA is surrounded by the partition 7 having a rectangular shape as an example of polygonal shapes, and further, each of the four sides of each closed area CA extends in an oblique direction intersecting with the first direction X and the second direction Y.

In other words, in a manner similar to that of the example explained with reference to FIG. 4, the partition 7 has a shape which is not orthogonal to the first direction X which is the extension direction of the first side 10X, or the arrangement direction AD of the terminals TE. Further, the partition 7 has a shape which is not orthogonal to the second direction Y which is the extension direction of the second side 10Y, the perpendicular direction PD or the cut lines CL.

In this manner, in this configuration example, similarly, even if application direction DX or application direction DY is selected at the time of the formation of the resist R1, the expansion of the resist R1 is not blocked by the partition 7. This configuration prevents the resist R1 from undesirably having a defective portion.

In addition, as the partition 7 forms the closed area CA, the removal of the multilayer film is prevented.

FIG. 27 is a diagram showing another configuration example of the partition 7.

The configuration example shown in FIG. 27 is different from that shown in FIG. 26 in respect that the partition 7 is formed into a grating shape comprising arcuate portions. Closed areas CA are formed inside the partition 7. Each closed area CA is surrounded by the circular partition 7 having a circular shape.

In other words, the partition 7 has a shape which is not orthogonal to the first direction X which is the extension direction of the first side 10X, or the arrangement direction AD of the terminals TE. Further, the partition 7 has a shape which is not orthogonal to the second direction Y which is the extension direction of the second side 10Y, the perpendicular direction PD or the cut lines CL.

In this configuration example, effects similar to those of the configuration example shown in FIG. 26 are obtained.

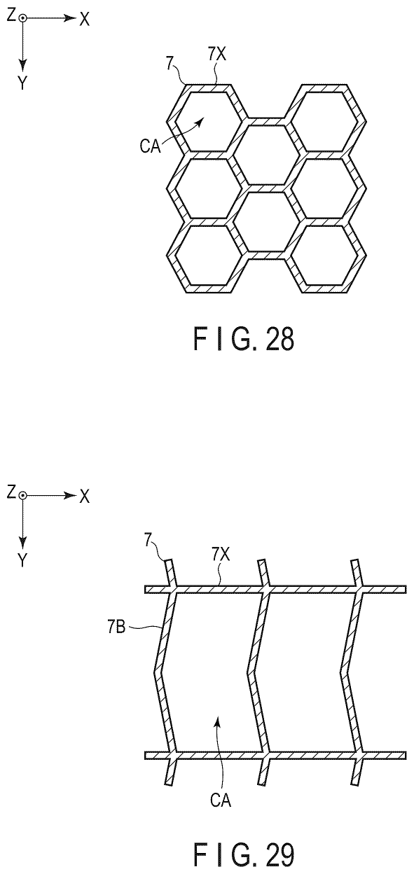

FIG. 28 is a diagram showing another configuration example of the partition 7.

The configuration example shown in FIG. 28 is different from that shown in FIG. 26 in respect that each closed area CA is surrounded by the partition 7 having a hexagonal shape as an example of polygonal shapes. In the example shown in the figure, the partition 7 includes sides 7X parallel to the first direction X. Each of the other sides extends in an oblique direction intersecting with the first direction X and the second direction Y.

In other words, the partition 7 has a shape which is not orthogonal to the first direction X which is the extension direction of the first side 10X, or the arrangement direction AD of the terminals TE.

Thus, in this configuration example, in a case where application direction DX is selected at the time of the formation of the resist R1, the expansion of the resist R1 is not blocked by the partition 7. This configuration can prevent the resist R1 from undesirably having a defective portion.

In addition, as the partition 7 forms the closed area CA, the removal of the multilayer film is prevented.

FIG. 29 is a diagram showing another configuration example of the partition 7.

The configuration example shown in FIG. 29 is different from that shown in FIG. 26 in respect that the partition 7 is formed into an oblique grating shape. The partition 7 surrounding a single closed area CA comprises sides 7X parallel to the first direction X, and sides 7B which are bent so as to intersect with the first direction X and the second direction Y.

In other words, the partition 7 has a shape which is not orthogonal to the first direction X which is the extension direction of the first side 10x, or the arrangement direction AD of the terminals TE.

Thus, in this configuration example, in a case where application direction DX is selected at the time of the formation of the resist R1, the expansion of the resist R1 is not blocked by the partition 7. This configuration can prevent the resist R1 from undesirably having a defective portion.

In addition, as the partition 7 forms the closed area CA, the removal of the multilayer film is prevented.

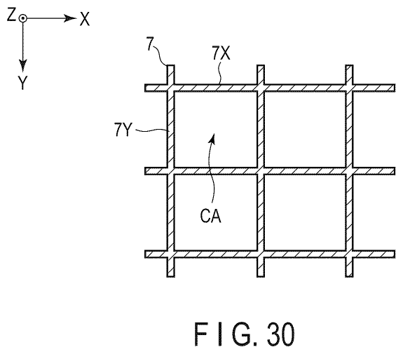

FIG. 30 is a diagram showing another configuration example of the partition 7.

The configuration example shown in FIG. 30 is different from that shown in FIG. 26 in respect that the partition 7 surrounding a single closed area CA is formed into a rectangular shape including sides 7X parallel to the first direction X and sides 7Y parallel to the second direction Y.

In this configuration example, as the partition 7 forms the closed area CA, the removal of the multilayer film is prevented.

In the above embodiment, for example, the partition 7 corresponds to a first partition. The lower portion 71 corresponds to a first lower portion. The upper portion 72 corresponds to a first upper portion. The partition 6 corresponds to a second partition. The lower portion 61 corresponds to a second lower portion. The upper portion 62 corresponds to a second upper portion. The segment SG1 corresponds to a first segment. The segment SG2 corresponds to a second segment. The segment SG3 corresponds to a third segment. The segment SG4 corresponds to a fourth segment.

As explained above, the present embodiment can provide a mother substrate, a display device and a manufacturing method of a display device such that the reduction in reliability can be prevented.

All of the mother substrates, the display devices and the manufacturing methods of the display devices that can be implemented by a person of ordinary skill in the art through arbitrary design changes to the mother substrate, the display device and the manufacturing method of the display device described above as the embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. A mother substrate for a display device, comprising:
a substrate comprising a linear first side;
a plurality of panel portions;
a margin portion provided on an external side relative to the panel portions; and
a first partition comprising a first lower portion provided in the margin portion, and a first upper portion provided on the first lower portion and protruding from a side surface of the first lower portion, wherein
the first partition has a shape which is not orthogonal to an extension direction of the first side.

2. The mother substrate of claim 1, wherein
each of the panel portions comprises:
a second partition comprising a second lower portion formed of a conductive material, and a second upper portion provided on the second lower portion and protruding from a side surface of the second lower portion;
a lower electrode surrounded by the second partition;
an organic layer provided on the lower electrode and including a light emitting layer; and
an upper electrode which covers the organic layer and is in contact with the second lower portion of the second partition.

3. The mother substrate of claim 2, further comprising an inorganic insulating layer provided over the panel portions and the margin portion and comprising an aperture overlapping the lower electrode, wherein
the first partition and the second partition are provided on the inorganic insulating layer.

4. The mother substrate of claim 1, wherein
the first partition comprises a plurality of segments each formed into a linear shape.

5. The mother substrate of claim 4, wherein
a first segment and a second segment arranged in the extension direction of the first side extend in directions different from each other, and
the first segment and a third segment arranged in a direction orthogonal to the extension direction of the first side extend in directions different from each other.

6. The mother substrate of claim 4, wherein
a first segment and a second segment arranged in the extension direction of the first side extend in directions different from each other, and
the first segment and a third segment arranged in a direction orthogonal to the extension direction of the first side are parallel to each other.

7. The mother substrate of claim 1, wherein
the first partition is formed into an independent loop shape.

8. The mother substrate of claim 7, wherein
the first partition is formed into a polygonal shape and comprises at least one side intersecting with the extension direction of the first side.

9. The mother substrate of claim 7, wherein
the first partition is formed into a circular shape.

10. The mother substrate of claim 1, wherein
the first partition is formed into a grating shape.

11. The mother substrate of claim 10, wherein
the first partition comprises at least one side intersecting with the extension direction of the first side.

12. The mother substrate of claim 10, wherein
the first partition comprises at least one arcuate portion.

13. A display device comprising:
a display area which displays an image;
a surrounding area provided on an external side relative to the display area;
a plurality of terminals arranged in a single direction in the surrounding area; and
a first partition comprising a first lower portion provided in the surrounding area, and a first upper portion provided on the first lower portion and protruding from a side surface of the first lower portion, wherein
the first partition has a shape which is not orthogonal to at least one of an arrangement direction of the terminals and a perpendicular direction orthogonal to the arrangement direction.

14. The display device of claim 13, further comprising:
a second partition provided in the display area, and comprising a second lower portion formed of a conductive material, and a second upper portion provided on the second lower portion and protruding from a side surface of the second lower portion;
a lower electrode surrounded by the second partition;
an organic layer provided on the lower electrode and including a light emitting layer; and
an upper electrode which covers the organic layer and is in contact with the second lower portion of the second partition.

15. The display device of claim 14, further comprising an inorganic insulating layer provided over the display area and the surrounding area and comprising an aperture overlapping the lower electrode, wherein
the first partition and the second partition are provided on the inorganic insulating layer.

16. The display device of claim 13, wherein
the first partition comprises a plurality of segments which linearly extend.

17. The display device of claim 13, wherein
the first partition is formed into an independent loop shape.

18. The display device of claim 13, wherein
the first partition is formed into a grating shape.

19. A manufacturing method of a display device, comprising:
forming a lower electrode in a display area which displays an image;
forming an inorganic insulating layer over the display area and a surrounding area provided on an external side relative to the display area;
forming, in the surrounding area, a first partition comprising a first lower portion located on the inorganic insulating layer, and a first upper portion located on the first lower portion and protruding from a side surface of the first lower portion; and
applying a resist, wherein
the first partition has a shape which is not orthogonal to an application direction of the resist.

20. The manufacturing method of claim 19, further comprising:
forming, in the display area, a second partition comprising a second lower portion located on the inorganic insulating layer, and a second upper portion located on the second lower portion and protruding from a side surface of the second lower portion, before applying the resist;
pattering the resist after applying the resist;
forming an aperture in the inorganic insulating layer overlapping the lower electrode by performing etching using the resist as a mask;
forming an organic layer including a light emitting layer on the lower electrode by performing vapor deposition using the second partition as a mask; and
forming an upper electrode which covers the organic layer and is in contact with the second lower portion of the second partition by performing vapor deposition using the second partition as a mask.
